(19) United States
(12) Patent Application Publication
(10) Pub. No.: US 2026/0037124 A1
(43) Pub. Date: Feb. 5, 2026

(54) STORAGE DEVICE INCLUDING NONVOLATILE MEMORY

(71) Applicant: SK hynix Inc., Icheon-si (KR)

(72) Inventor: Sung Lae OH, Icheon-si (KR)

(73) Assignee: SK hynix Inc., Icheon-si (KR)

(21) Appl. No.: 18/972,912

(22) Filed: Dec. 7, 2024

(30) Foreign Application Priority Data
Aug. 5, 2024 (KR) 10-2024-0103539

(51) Int. Cl. G06F 3/06; G11C 16/04; H01L 25/16; H10B 80/00

(52) U.S. Cl. CPC G06F 3/0608; G06F 3/0659; G06F 3/0679; H01L 25/16; H10B 80/00; G11C 16/0483

(57) ABSTRACT

A storage device includes a memory device and a controller. The memory device includes a first wafer including a plurality of first word lines vertically stacked and a plurality of first memory cells connected to the plurality of first word lines; and a second wafer including a plurality of second word lines and a plurality of third word lines vertically stacked, a plurality of second memory cells connected to the plurality of second word lines, and a plurality of third memory cells connected to the plurality of third word lines. The controller encodes first type of data to generate first and second codes, stores the first code in one of the first memory cells, stores the second code in one of the second memory cells, encodes second type of data to generate a third code, and stores the third code in one of the third memory cells.

### CROSS-REFERENCE TO RELATED APPLICATION

The present application claims priority under 35 U.S.C. § 119(a) to Korean Patent Application No. 10-2024-0103539 filed in the Korean Intellectual Property Office on Aug. 5, 2024, which is incorporated herein by reference in its entirety.

### BACKGROUND

### 1. Technical Field

Various embodiments generally relate to a semiconductor technology, and more particularly, to a storage device including a nonvolatile memory.

### 2. Related Art

In response to the demand for high integration, multi-level cells capable of storing more than two bits of data in one memory cell have been proposed. However, as the number of bits stored in one memory cell increases, the difference in threshold voltage between adjacent bits decreases, and thus, the rate of read failures increases. For this reason, improving storage density using multi-level cells is challenging.

### SUMMARY

Embodiments of the present disclosure are directed to providing a storage device including a nonvolatile memory.

In an embodiment, a storage device may include a memory device and a controller. The memory device may include: a first wafer including a plurality of first word lines that are vertically stacked and a plurality of first memory cells that are connected to the plurality of first word lines; and a second wafer including a plurality of second word lines and a plurality of third word lines that are vertically stacked, a plurality of second memory cells that are connected to the plurality of second word lines, and a plurality of third memory cells that are connected to the plurality of third word lines. The controller may encode a first type of data to generate a first code and a second code, may store the first code in one of the plurality of first memory cells, and may store the second code in one of the plurality of second memory cells. The controller may encode a second type of data to generate a third code, and may store the third code in one of the plurality of third memory cells.

In an embodiment, a storage device may include a memory device having a first wafer and a second wafer that vertically overlap each other; and a controller. The first wafer may include: a plurality of first word lines that are vertically stacked; a plurality of odd cell plugs that vertically pass through the plurality of first word lines and are connected to a plurality of odd bit lines; and a plurality of first memory cells that are disposed in areas where the plurality of first word lines surround the plurality of odd cell plugs. The second wafer may include: a plurality of second word lines and a plurality of third word lines that are vertically stacked; a plurality of even cell plugs that vertically pass through the pluralities of second and third word lines and are connected to a plurality of even bit lines; a plurality of second memory cells that are disposed in areas where the plurality of second word lines surround the plurality of even cell plugs; and a plurality of third memory cells that are disposed in areas where the plurality of third word lines surround the plurality of even cell plugs. The controller may encode a first type of data to generate a first code and a second code, may store the first code in one of the plurality of first memory cells, and may store the second code in one of the plurality of second memory cells. The controller may encode a second type of data to generate a third code, and may store the third code in one of the plurality of third memory cells.

In an embodiment, a storage device may include a memory device having a first wafer and a second wafer that vertically overlap each other; and a controller. The first wafer may include: a plurality of first word lines and a plurality of second word lines that are vertically stacked; a plurality of first memory cells that are connected to the plurality of first word lines; and a plurality of second memory cells that are connected to the plurality of second word lines. The second wafer may include: a plurality of third word lines and a plurality of fourth word lines that are vertically stacked; a plurality of third memory cells that are connected to the plurality of third word lines; and a plurality of fourth memory cells that are connected to the plurality of fourth word lines. The controller may encode a first type of data to generate a first code and a second code, may store the first code in one of the plurality of first memory cells, and may store the second code in one of the plurality of third memory cells. The controller may encode a second type of data to generate a third code, and may store the third code in one of the pluralities of second and fourth memory cells.

In an embodiment, a storage device may include a memory device including a first wafer and a second wafer that vertically overlap each other; and a controller. The first wafer may include: a plurality of first word lines that are vertically stacked; a plurality of first cell plugs that vertically pass through the plurality of first word lines; and a plurality of first memory cells that are disposed in areas where the plurality of first word lines surround the plurality of first cell plugs. The second wafer may include: a plurality of second word lines that are vertically stacked; a plurality of second cell plugs that vertically pass through the plurality of second word lines; and a plurality of second memory cells that are disposed in areas where the plurality of second word lines surround the plurality of second cell plugs. The controller may encode data to generate a first code and a second code, may store the first code in one of the plurality of first memory cells, and may store the second code in one of the plurality of second memory cells.

According to the embodiments of the present disclosure, large-capacity memories may be fabricated in small sizes, and memory usage efficiency may be improved.

### BRIEF DESCRIPTION OF THE DRAWINGS

FIG. 1 is a block diagram schematically illustrating a storage device according to an embodiment of the present disclosure.

FIG. 2 is a cross-sectional view of a memory device of FIG. 1.

FIG. 3 is a block diagram schematically illustrating a controller of FIG. 1.

FIG. 4 is a schematic diagram for explaining a method for storing first type data in a storage device according to an embodiment of the present disclosure.

FIG. 5 is a diagram illustrating a memory device related to the present disclosure.

FIG. 6 is a diagram illustrating a memory device according to an embodiment of the present disclosure.

FIGS. 7 to 12 are cross-sectional views illustrating memory devices according to embodiments of the present disclosure.

FIG. 13 is a block diagram schematically illustrating a storage device according to an embodiment of the present disclosure.

FIG. 14 is a cross-sectional view of a memory device of FIG. 13.

FIG. 15 is a block diagram schematically illustrating a storage device according to an embodiment of the present disclosure.

FIG. 16 is a cross-sectional view of a memory device of FIG. 15.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through one or more intervening elements. When two elements are identified as “directly connected” or “directly coupled,” one element is directly connected or directly coupled to the other element without any intervening element.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise to limit scope. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

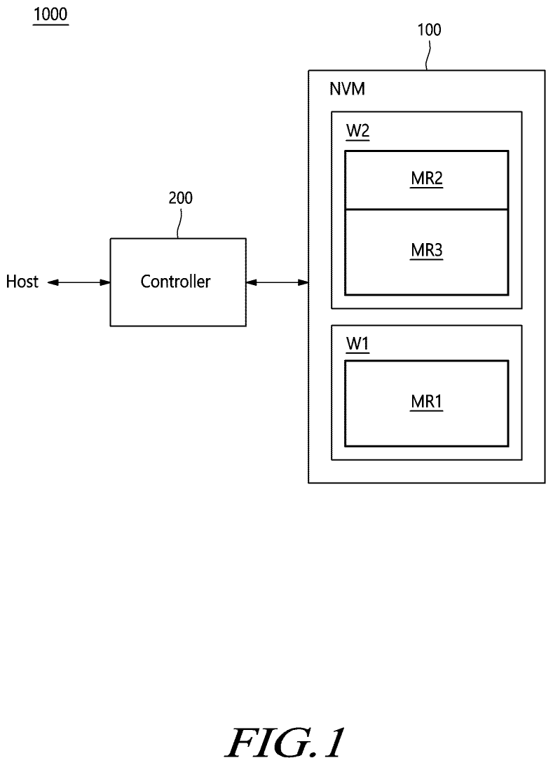

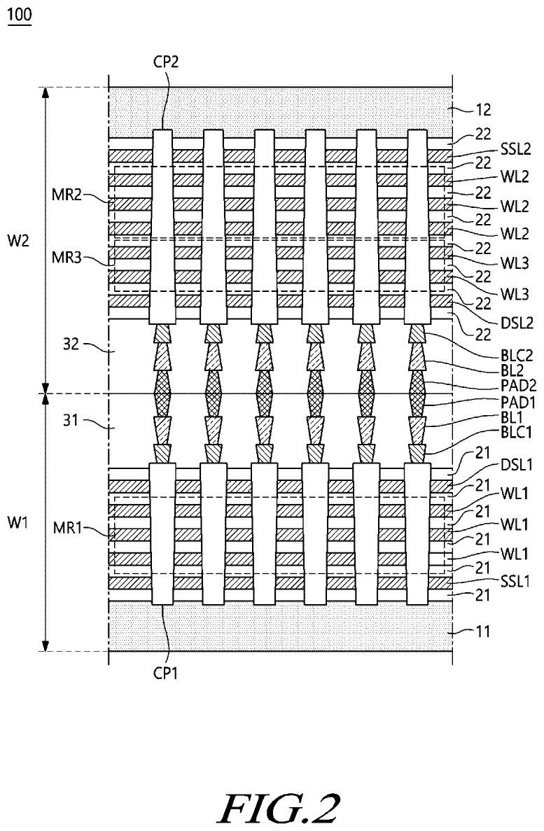

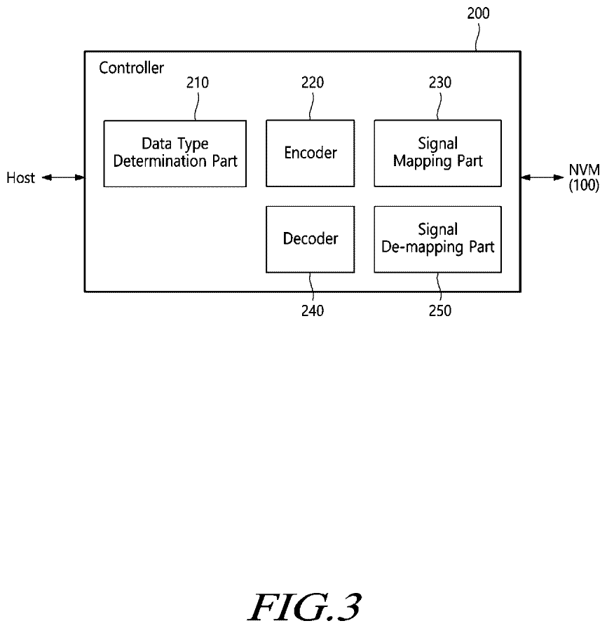

FIG. 1 is a block diagram schematically illustrating a storage device according to an embodiment of the present disclosure, FIG. 2 is a cross-sectional view of a memory device of FIG. 1, and FIG. 3 is a block diagram schematically illustrating a controller of FIG. 1.

Referring to FIG. 1, a storage device 1000 includes a memory device 100 and a controller 200.

The memory device 100 includes a first wafer W1 and a second wafer W2. The first wafer W1 includes a first memory region MR1, and the second wafer W2 includes a second memory region MR2 and a third memory region MR3.

The first memory region MR1 includes a plurality of first word lines and first memory cells, which are connected to the plurality of first word lines. The second memory region MR2 includes a plurality of second word lines and second memory cells, which are connected to the plurality of second word lines. The third memory region MR3 includes a plurality of third word lines and third memory cells, which are connected to the plurality of third word lines.

The memory device 100 may be a nonvolatile memory device. In an embodiment, the memory device 100 may be NAND flash memory having a three-dimensional structure, and the first, second and third memory cells may be NAND flash memory cells that are three-dimensionally arranged.

The controller 200 may classify write data into a first type or a second type. The first type of data may be cold data, and the second type of data may be hot data.

The controller 200 may encode the first type of data to generate a first code and a second code, may store the first code in one of the first memory cells of the first memory region MR1, and may store the second code in one of the second memory cells of the second memory region MR2. The controller 200 may encode the second type of data to generate a third code, and may store the third code in one of the third memory cells of the third memory region MR3.

Referring to FIG. 2, the first wafer W1 and the second wafer W2 vertically overlap each other. The first wafer W1 and the second wafer W2 may be manufactured separately from each other, and then, may be coupled to each other by a bonding technique. The first wafer W1 and the second wafer W2 may be bonded to each other by hybrid bonding. The memory device 100 according to an embodiment has a non-monolithic structure.

The first wafer W1 includes a first substrate 11, a plurality of first cell plugs CP1 which extend vertically from the first substrate 11, and a first source select line SSL1, a plurality of first word lines WL1 and a first drain select line DSL1, which are vertically stacked on the first substrate 11 and surround the first cell plugs CP1.

The first source select line SSL1 is disposed between a lowermost first word line WL1 among the plurality of first word lines WL1 and the first substrate 11, and the first drain select line DSL1 is disposed on an uppermost first word line WL1 among the plurality of first word lines WL1. Although embodiments of the present disclosure include one layer of each of the first source select line SSL1 and the first drain select line DSL1, the present disclosure is not limited thereto. At least one of the first source select line SSL1 and the first drain select line DSL1 may be provided as at least two layers.

First interlayer insulating layers 21 are disposed to insulate the first source select line SSL1, the first word lines WL1 and the first drain select line DSL1 from each other. The first interlayer insulating layers 21 are alternately stacked with the first source select line SSL1, the first word lines WL1 and the first drain select line DSL1, thereby isolating the first source select line SSL1, the first word lines WL1 and the first drain select line DSL1 from each other.

The first cell plugs CP1 extend into the first substrate 11 by vertically passing through the first drain select line DSL1, the first word lines WL1, the first source select line SSL1 and the first interlayer insulating layers 21.

Although not illustrated in detail, a first cell plug CP1 may include a channel layer and a memory layer. The channel layer may include a semiconductor material. For example, the channel layer may include polysilicon. The memory layer may have a straw or cylinder shell shape, which surrounds the outer wall of the channel layer. The memory layer may include a tunnel insulating layer, which surrounds the channel layer, a data storage layer, which surrounds the tunnel insulating layer, and a blocking layer, which surrounds the data storage layer.

First source select transistors may be configured in areas where the first source select line SSL1 surrounds the first cell plugs CP1. First memory cells may be configured in areas where the first word lines WL1 surround the first cell plugs CP1. First drain select transistors may be configured in areas where the first drain select line DSL1 surrounds the first cell plugs CP1. The first memory region MR1 includes the first word lines WL1 and the first memory cells.

The first cell plug CP1 is connected to a corresponding first bit line BL1 through a first bit line contact BLC1. The first wafer W1 has a bonding surface, which is bonded to the second wafer W2, and includes a plurality of first bonding pads PAD1, which are disposed on the bonding surface. Each first bit line BL1 may correspond to one of the plurality of first bonding pads PAD1, and may be connected to a corresponding first bonding pad PAD1.

The second wafer W2 includes a second substrate 12, a plurality of second cell plugs CP2, which extend vertically from the second substrate 12, and a second source select line SSL2, a plurality of second word lines WL2, a plurality of third word lines WL3 and a second drain select line DSL2, which are vertically stacked below the second substrate 12 to surround the second cell plugs CP2.

The second word lines WL2 may correspond one-to-one to the first word lines WL1. The number of the second word lines WL2 may be the same as the number of the first word lines WL1.

The plurality of second word lines WL2 may be disposed closer to the second substrate 12 than the plurality of third word lines WL3. The second wafer W2 has a bonding surface, which is bonded to the first wafer W1, and the plurality of third word lines WL3 may be disposed closer to the bonding surface than the plurality of second word lines WL2.

The second source select line SSL2 is disposed between an uppermost second word line WL2 among the plurality of second word lines WL2 and the second substrate 12, and the second drain select line DSL2 is disposed below a lowermost third word line WL3 among the plurality of third word lines WL3. Although embodiments of the present disclosure include one layer of each of the second source select line SSL2 and the second drain select line DSL2, the present disclosure is not limited thereto. At least one of the second source select line SSL2 and the second drain select line DSL2 may be provided as at least two layers.

Second interlayer insulating layers 22 are disposed to insulate the second source select line SSL2, the second word lines WL2, the third word lines WL3 and the second drain select line DSL2 from each other. The second interlayer insulating layers 22 are alternately stacked with the second source select line SSL2, the second word lines WL2, the third word lines WL3 and the second drain select line DSL2, thereby isolating the second source select line SSL2, the second word lines WL2, the third word lines WL3 and the second drain select line DSL2 from each other.

The second cell plugs CP2 extend into the second substrate 12 by vertically passing through the second drain select line DSL2, the third word lines WL3, the second word lines WL2, the second source select line SSL2 and the second interlayer insulating layers 22.

Second source select transistors may be configured in areas where the second source select line SSL2 surrounds the second cell plugs CP2. Second memory cells may be configured in areas where the second word lines WL2 surround the second cell plugs CP2. Third memory cells may be configured in areas where the third word lines WL3 surround the second cell plugs CP2. Second drain select transistors may be configured in areas where the second drain select line DSL2 surrounds the second cell plugs CP2.

The second memory region MR2 includes the second word lines WL2 and the second memory cells. The third memory region MR3 includes the third word lines WL3 and the third memory cells.

Each second cell plug CP2 is connected to a corresponding second bit line BL2 through a second bit line contact BLC2. The second wafer W2 has the bonding surface, which is bonded to the first wafer W1, and includes a plurality of second bonding pads PAD2, which are disposed on the bonding surface. Each second bit line BL2 may correspond to one of the plurality of second bonding pads PAD2, and may be connected to a corresponding second bonding pad PAD2. Drawing symbols 31 and 32 indicate insulating layers.

Referring to FIG. 3, the controller 200 may include a data type determination part 210, an encoder 220, a signal mapping part 230, a decoder 240 and a signal de-mapping part 250.

The data type determination part 210 may classify data to write into the first type of data or the second type of data. The first type of data may be cold data, and the second type of data may be hot data.

The data type determination part 210 may determine data to write as hot data or cold data on the basis of update frequency. In an embodiment, the data type determination part 210 may determine data whose update count is equal to or greater than a threshold as hot data, and may determine data whose update count is less than the threshold as cold data. As another example, the data type determination part 210 may determine data, whose count of updates that occurred during a predetermined past time period in reference to a current time point is equal to or greater than a threshold, as hot data, and may determine the other data as cold data. As still another example, the data type determination part 210 may also determine hot data or cold data by predicting an update frequency according to an attribute of a file.

In another embodiment, hot data or cold data determination for data to write may be performed by a host instead of the controller 200, and the host may provide information on a determination result to the controller 200. In this case, the data type determination part 210 may be omitted.

The encoder 220 encodes the first type of data (n bits) using a first map table to generate first codes and second codes. The first map table defines a first code and a second code, which match each of 2ⁿ number of data with n bits. Each of the first code and the second code is k bits where k is less than n.

The encoder 220 encodes the second type of data (m bits) using a second map table to generate third codes. The second map table defines a third code which matches each of 2^{m} number of data with m bits.

The signal mapping part 230 performs code-state mapping on each of the first code and the second code, thereby generating a first input pulse according to the first code and a second input pulse according to the second code. The first code is stored in a first memory cell as the first input pulse is applied to the first memory cell, and the second code is stored in a second memory cell as the second input pulse is applied to the second memory cell.

The signal mapping part 230 performs code-state mapping on the third code, thereby generating a third input pulse according to the third code. The third code is stored in a third memory cell as the third input pulse is applied to the third memory cell.

The signal de-mapping part 250 generates a de-mapped first code and a de-mapped second code from a first output pulse received from the first memory cell and a second output pulse received from the second memory cell, by using code-state mapping information used to generate the first input pulse and the second input pulse. The signal de-mapping part 250 generates the de-mapped first code corresponding to the first output pulse and the de-mapped second code corresponding to the second output pulse, by comparing each of the first output pulse and the second output pulse to threshold voltages with 2^{k} number of dispersions of memory cells of k bits.

The signal de-mapping part 250 generates a de-mapped third code from a third output pulse received from the third memory cell, by using code-state mapping information used to generate the third input pulse.

The decoder 240 restores original data (the first type of data) by decoding the de-mapped first code and the de-mapped second code using the first map table. The decoder 240 restores original data (the second type of data) by decoding the de-mapped third code using the second map table.

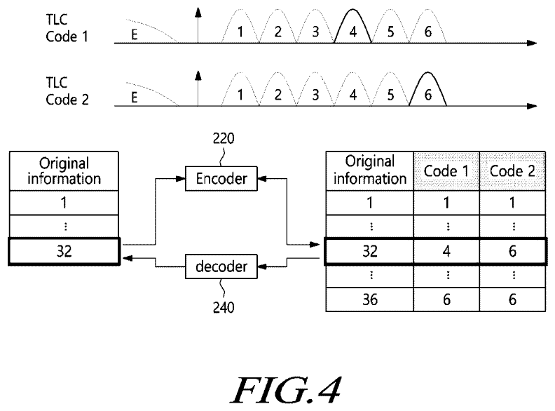

FIG. 4 is a schematic diagram for explaining a method for storing first type data in a storage device according to an embodiment of the present disclosure.

In FIG. 4, k is 2.6-bit, and each of a first code Code 1 and a second code Code 2 matches one of six program states.

Each of the first code Code 1 and the second code Code 2 has six numbers corresponding to six program states. The first map table may be configured by matching original information (data) to each of combination codes generated by combining six first codes Code 1 and six second codes Code 2. The number of the combination codes generated by combining the six first codes and the six second codes is 36, and the 36 combination codes are matched to 36 original information (data), respectively.

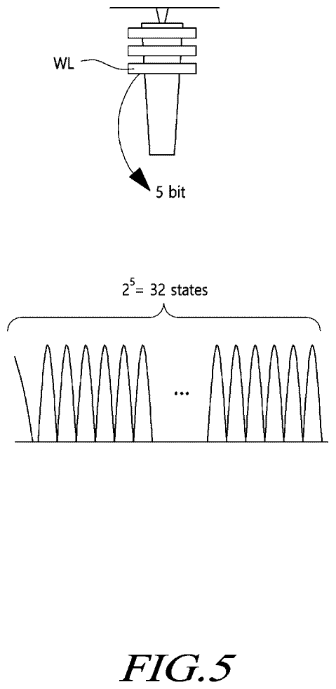

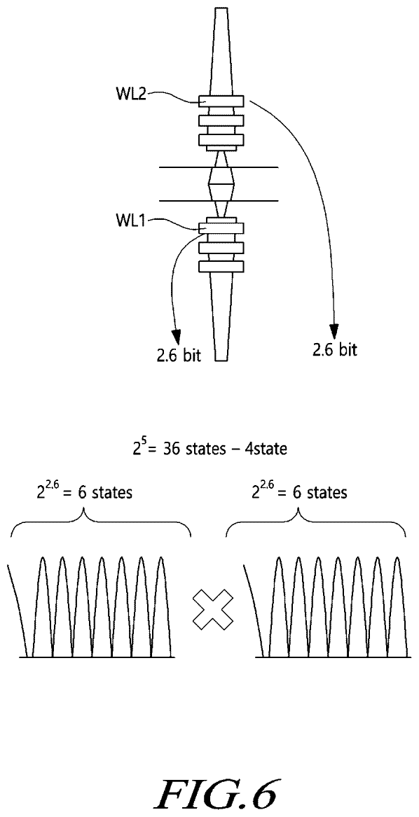

FIG. 5 is a diagram illustrating a memory device related to the present disclosure, and FIG. 6 is a diagram illustrating a memory device according to an embodiment of the present disclosure.

Since an n-bit memory cell can store n bits of data, 2ⁿ number of dispersions can be formed. In FIG. 5, n is 5, and 2⁵ number of dispersions can be formed to store 5 bits of data. However, as n increases, the difference in threshold voltage between adjacent bits decreases, and the width of the threshold voltage distribution of each bit decreases. Therefore, the possibility of an error to occur during writing and reading of memory cells increases.

Referring to FIG. 6, according to an embodiment, a 2.6-bit first code and a 2.6-bit second code are generated by encoding 5-bit data, and the first code and the second code are written to a 2.6-bit first memory cell with six dispersions and a 2.6-bit second memory cell with six dispersions, respectively. That is to say, 5-bit data may be stored using two memory cells with 6 dispersions.

Accordingly, as the difference in threshold voltage between adjacent bits becomes wider than the example of FIG. 5, it is possible to reduce the possibility of an error that may occur during writing and reading of memory cells. In addition, since two memory cells that store data are disposed to vertically overlap each other, there is no increase in area needed due to an increase in the number of memory cells used for data storage.

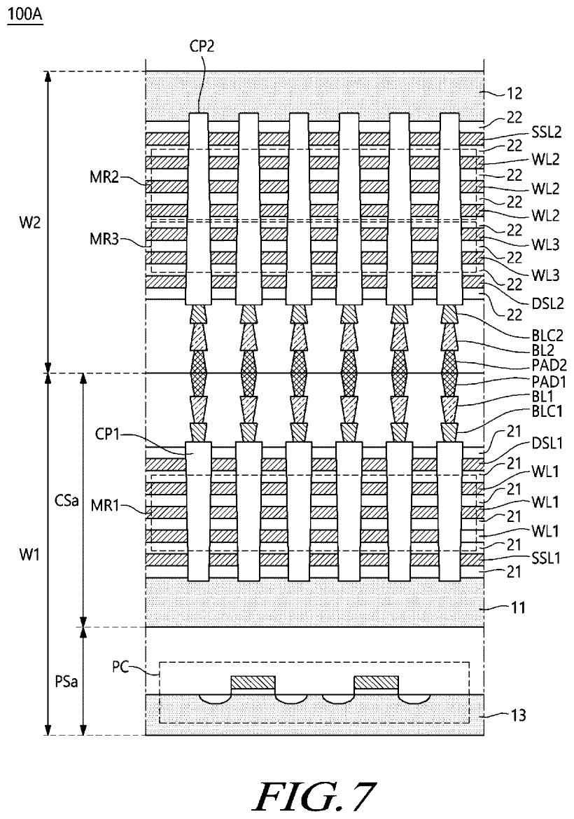

FIGS. 7 to 12 are cross-sectional views illustrating memory devices according to embodiments of the present disclosure. For the sake of simplicity in explanation, configurations or elements that overlap those described above with reference to FIG. 2 will be briefly described or omitted.

Referring to FIG. 7, a memory device 100A includes a first wafer W1 and a second wafer W2 that is bonded onto the first wafer W1.

The first wafer W1 includes a logic structure PSa and a memory structure CSa that is disposed on the logic structure PSa. In an embodiment of the present disclosure, after the logic structure PSa is formed first, the memory structure CSa may be formed on the logic structure PSa. In another embodiment of the present disclosure, the logic structure PSa may be formed on the memory structure CSa after the memory structure CSa may be formed.

The memory structure CSa may have a structure that is the same as or similar to the first wafer W1 of FIG. 2.

The logic structure PSa includes a third substrate 13 and a peripheral circuit PC that is defined on the third substrate 13. The peripheral circuit PC may serve to control first, second and third memory cells. The peripheral circuit PC may include a plurality of semiconductor elements such as transistors, resistors and capacitors. The peripheral circuit PC may include a plurality of functional blocks. For example, the peripheral circuit PC may include a row decoder, a page buffer circuit, a control logic, a voltage generator and an input/output circuit. At least a portion of the peripheral circuit PC may overlap with the first memory cells in a vertical direction. The first wafer W1 may have a PUC (peripheral under cell) structure.

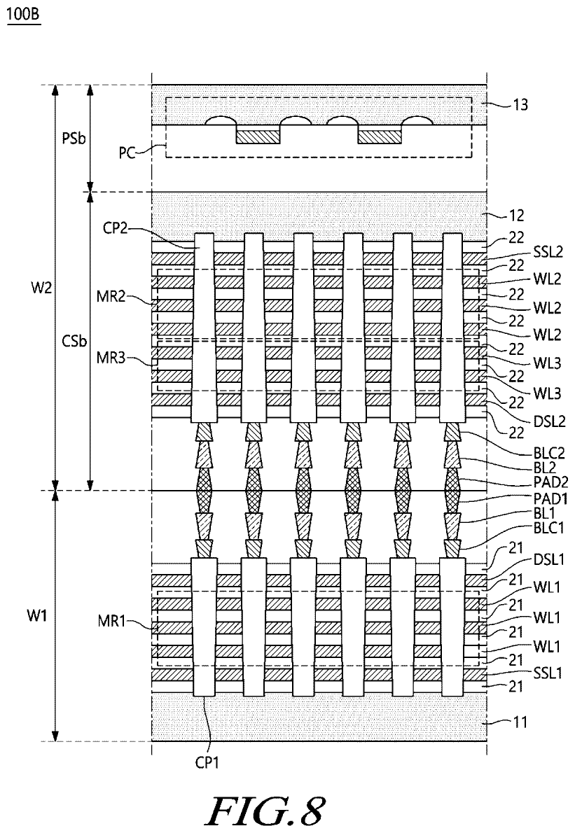

Referring to FIG. 8, a memory device 100B includes a first wafer W1 and a second wafer W2 that is bonded onto the first wafer W1.

The second wafer W2 includes a memory structure CSb and a logic structure PSb that is disposed on the memory structure CSb. For example, after the logic structure PSb is formed first, the memory structure CSb may be formed on the logic structure PSb to define the second wafer W2. In another embodiment of the present disclosure, the logic structure PSb may be formed on the memory structure CSb after the memory structure CSb may be formed In a state in which the second wafer W2 is turned upside down, the second wafer W2 may be bonded onto the first wafer W1.

The memory structure CSb may have a structure that is the same as or similar to a memory structure of the second wafer W2 of FIG. 2.

The logic structure PSb includes a third substrate 13 and a peripheral circuit PC that is defined under the third substrate 13. The peripheral circuit PC may serve to control first, second and third memory cells. The peripheral circuit PC may have the same or a similar configuration as or to the peripheral circuit PC of FIG. 7. At least a portion of the peripheral circuit PC may vertically overlap with the second memory cells and the third memory cells. The second wafer W2 may have a PUC structure.

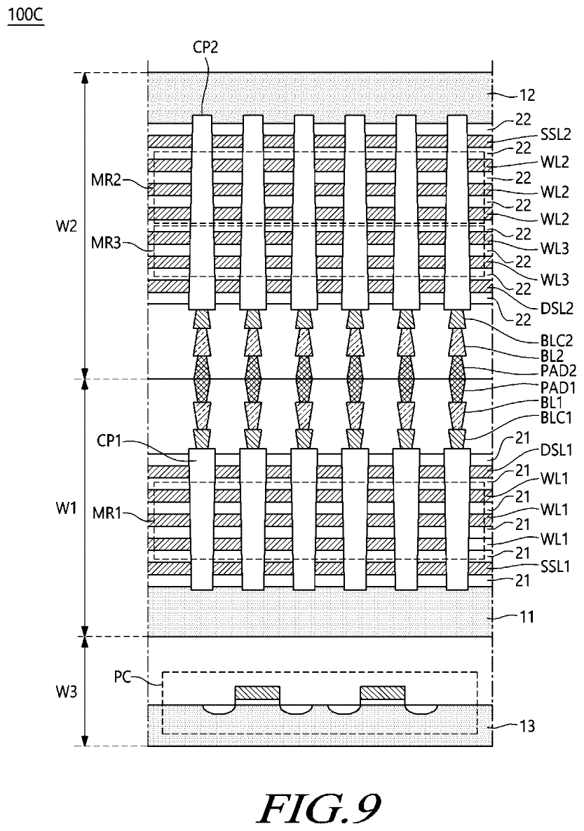

Referring to FIG. 9, a memory device 100C may include a first wafer W1, a second wafer W2 and a third wafer W3, which vertically overlap each other.

The third wafer W3 includes a third substrate 13 and a peripheral circuit PC that is defined on the third substrate 13. The peripheral circuit PC may serve to control first, second and third memory cells. The peripheral circuit PC may have the same or similar configuration as or to the peripheral circuit PC of FIG. 7. The third wafer W3 is fabricated separately from the first and second wafers W1 and W2 and is then bonded to the first wafer W1 by a bonding technique. Since the peripheral circuit PC is fabricated on a separate wafer from the first, second and third memory cells and is not affected by a thermal process for forming the first, second and third memory cells, it is possible to prevent the peripheral circuit PC from degrading due to a thermal process.

In FIG. 9, the third wafer W3 is bonded to the first wafer W1, but the location of the third wafer W3 is not limited thereto. For example, the third wafer W3 may be bonded to the second wafer W2.

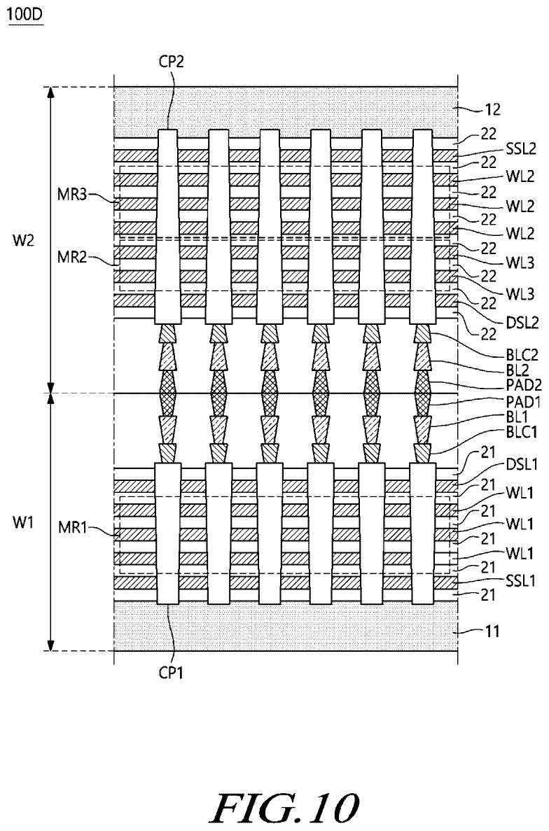

Referring to FIG. 10, a memory device 100D includes a first wafer W1 and a second wafer W2 that is bonded onto the first wafer W1.

The second wafer W2 includes a second substrate 12, a plurality of second cell plugs CP2 that extend vertically from the second substrate 12, and a second source select line SSL2, a plurality of third word lines WL3, a plurality of second word lines WL2 and a second drain select line DSL2, which are vertically stacked below the second substrate 12 to surround the second cell plugs CP2.

The second wafer W2 has a bonding surface that is bonded to the first wafer W1, and the plurality of second word lines WL2 may be disposed closer to the bonding surface than the plurality of third word lines WL3. A second memory region MR2 may be disposed closer to the bonding surface than a third memory region MR3.

The second source select line SSL2 is disposed between an uppermost third word line WL3 among the plurality of third word lines WL3 and the second substrate 12, and the second drain select line DSL2 is disposed below a lowermost second word line WL2 among the plurality of second word lines WL2.

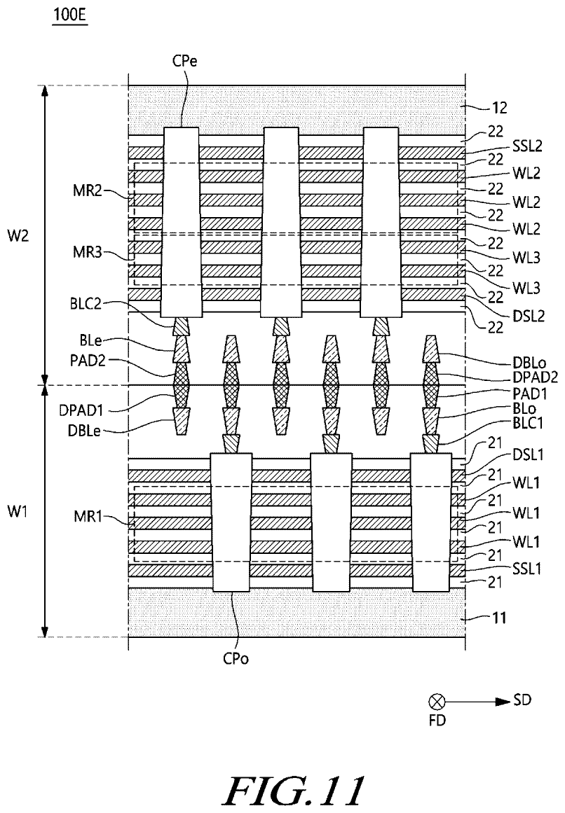

Referring to FIG. 11, a memory device 100E includes a first wafer W1 and a second wafer W2 that is bonded onto the first wafer W1.

The first wafer W1 includes a plurality of odd bit lines BLo, a plurality of dummy even bit lines DBLe and a plurality of odd cell plugs CPo.

The plurality of odd cell plugs CPo extend into a first substrate 11 by vertically passing through a first drain select line DSL1, first word lines WL1, a first source select line SSL1 and first interlayer insulating layers 21.

First source select transistors may be configured in areas where the first source select line SSL1 surrounds the odd cell plugs CPo. First memory cells may be configured in areas where the first word lines WL1 surround the odd cell plugs CPo. First drain select transistors may be configured in areas where the first drain select line DSL1 surrounds the odd cell plugs CPo. A first memory region MR1 includes the first word lines WL1 and the first memory cells that are connected to the first word lines WL1.

The plurality of odd bit lines BLo and the plurality of dummy even bit lines DBLe extend in a first direction FD, and are alternately disposed in a second direction SD intersecting the first direction FD.

Each odd cell plug CPo corresponds to one of the odd bit lines BLo, and is connected to a corresponding odd bit line BLo through a first bit line contact BLC1.

The first wafer W1 has a bonding surface that is bonded to the second wafer W2, and includes a plurality of first bonding pads PAD1 and a plurality of first dummy bonding pads DPAD1 that are disposed on the bonding surface. Each odd bit line BLo corresponds to one of the plurality of first bonding pads PAD1, and is connected to a corresponding first bonding pad PAD1. Each dummy even bit line DBLe corresponds to one of the plurality of first dummy bonding pads DPAD1, and is connected to a corresponding first dummy bonding pad DPAD1.

The second wafer W2 includes a plurality of even bit lines BLe, a plurality of dummy odd bit lines DBLo and a plurality of even cell plugs CPe.

The plurality of even cell plugs CPe extend into a second substrate 12 by vertically passing through a second drain select line DSL2, third word lines WL3, second word lines WL2, a second source select line SSL2 and second interlayer insulating layers 22.

Second source select transistors may be configured in areas where the second source select line SSL2 surrounds the even cell plugs CPe. Second memory cells may be configured in areas where the second word lines WL2 surround the even cell plugs CPe. Third memory cells may be configured in areas where the third word lines WL3 surround the even cell plugs CPe. Second drain select transistors may be configured in areas where the second drain select line DSL2 surrounds the even cell plugs CPe.

A second memory region MR2 includes the second word lines WL2 and the second memory cells that are connected to the second word lines WL2. A third memory region MR3 includes the third word lines WL3 and the third memory cells that are connected to the third word lines WL3.

The plurality even bit lines BLe and the plurality of dummy odd bit lines DBLo extend in the first direction FD, and are alternately disposed in the second direction SD

The even bit lines BLe of the second wafer W2 correspond to the dummy even bit lines DBLe, respectively, of the first wafer W1, and may each vertically overlap a corresponding dummy even bit line DBLe. The dummy odd bit lines DBLo of the second wafer W2 correspond to the odd bit lines BLo, respectively, of the first wafer W1, and may each vertically overlap a corresponding odd bit line BLo.

Each even cell plug CPe of the second wafer W2 corresponds to one of the even bit lines BLe of the second wafer W2, and is connected to a corresponding even bit line BLe through a second bit line contact BLC2. The even cell plugs CPe of the second wafer W2 may be disposed not to be vertically aligned with but to be offset from the odd cell plugs CPo of the first wafer W1.

The second wafer W2 has a bonding surface that is bonded to the first wafer W1, and includes a plurality of second bonding pads PAD2 and a plurality of second dummy bonding pads DPAD2 that are disposed on the bonding surface. Each even bit line BLe of the second wafer W2 corresponds to one of the plurality of second bonding pads PAD2, and is connected to a corresponding second bonding pad PAD2. Each dummy odd bit line DBLo of the second wafer W2 corresponds to one of the plurality of second dummy bonding pads DPAD2, and is connected to a corresponding second dummy bonding pad DPAD2.

The first memory cells of the first memory region MR1 are connected to the odd bit lines BLo of the first wafer W1, and the second memory cells of the second memory region MR2 and the third memory cells of the third memory region MR3 are connected to the even bit lines BLe of the second wafer W2.

A controller (200 of FIG. 1) encodes first type of data to generate a first code and a second code. The first code may be transmitted to the first memory region MR1 through an odd bit line BLo and be stored in one of the first memory cells of the first memory region MR1, and the second code may be transmitted to the second memory region MR2 through an even bit line BLe and be stored in one of the second memory cells of the second memory region MR2. The controller (200 of FIG. 1) encodes second type of data to generate a third code. The third code may be transmitted to the third memory region MR3 through an even bit line BLe and be stored in one of the third memory cells of the third memory region MR3.

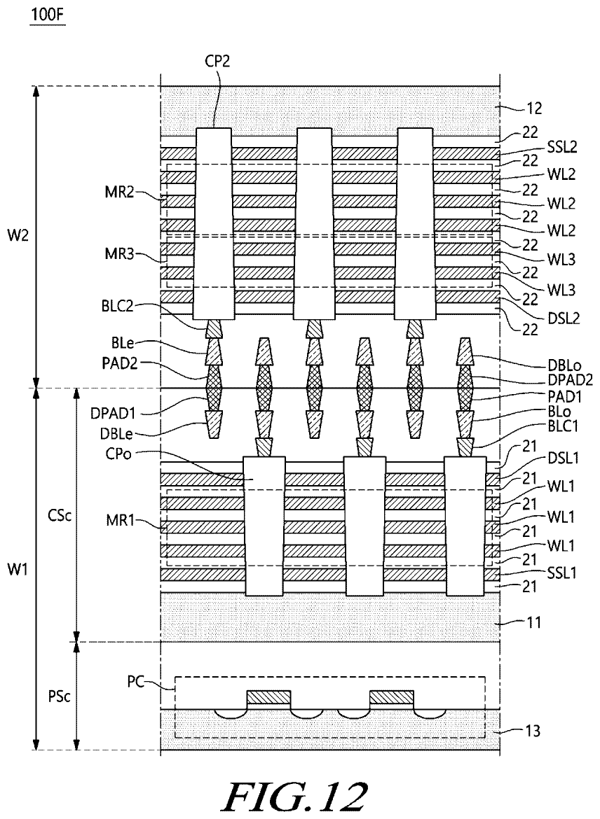

Referring to FIG. 12, a memory device 100F includes a first wafer W1 and a second wafer W2 that is bonded onto the first wafer W1.

The first wafer W1 includes a logic structure PSc and a memory structure CSc that is disposed on the logic structure PSc. After the logic structure PSc is formed first, the memory structure CSc may be formed on the logic structure PSc. In another embodiment of the present disclosure, the logic structure PSc may be formed on the memory structure CSc after the memory structure CSc may be formed.

The memory structure CSc may have a structure that is the same as or similar to the first wafer W1 of FIG. 11.

The logic structure PSc includes a third substrate 13 and a peripheral circuit PC that is defined on the third substrate 13. The peripheral circuit PC may serve to control first, second and third memory cells. The peripheral circuit PC may include a plurality of semiconductor elements such as transistors, resistors and capacitors. The peripheral circuit PC may include a plurality of functional blocks. For example, the peripheral circuit PC may include a row decoder, a page buffer circuit, a control logic, a voltage generator and an input/output circuit.

The page buffer circuit may include a plurality of page buffers. One of the odd bit lines BLo of the first wafer W1 and one of the even bit lines BLe of the second wafer W2 may share one page buffer. The odd bit line BLo and the even bit lines BLe that share the one page buffer may be alternatively connected to the page buffer.

In FIG. 12, the logic structure PSc including the peripheral circuit PC is included in the first wafer W1, but the present disclosure is not limited thereto. As another example, a logic structure may be included in a second wafer. As still another example, a peripheral circuit may be included in a third wafer which is defined separately from a first and a second wafer, and the third wafer may be bonded to one of the first wafer and the second wafer.

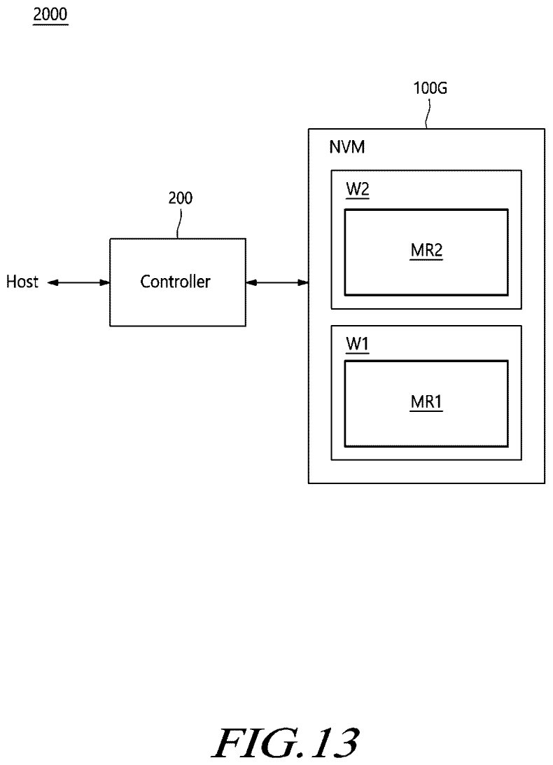

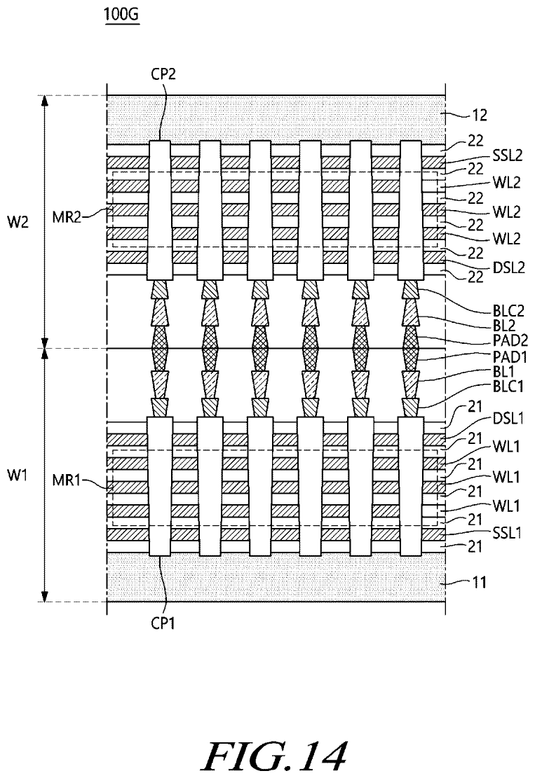

FIG. 13 is a block diagram schematically illustrating a storage device according to an embodiment of the present disclosure, and FIG. 14 is a cross-sectional view of a memory device of FIG. 13. For the sake of simplicity in explanation, configurations that overlap those described above with reference to FIGS. 1 and 2 will be briefly described or omitted.

Referring to FIG. 13, a storage device 2000 according to the embodiment of the present disclosure includes a memory device 100G and a controller 200. The memory device 100G may be a non-volatile memory NVM.

The memory device 100G includes a first wafer W1 and a second wafer W2. The first wafer W1 includes a first memory region MR1, and the second wafer W2 includes a second memory region MR2.

The first memory region MR1 includes a plurality of first word lines and first memory cells that are connected to the plurality of first word lines. The second memory region MR2 includes a plurality of second word lines and second memory cells, which are connected to the plurality of second word lines.

The controller 200 may encode data to write regardless of any attribute of the data to generate a first code and a second code, may store the first code in one of the first memory cells of the first memory region MR1, and may store the second code in one of the second memory cells of the second memory region MR2.

Referring to FIG. 14, the memory device 100G includes the first wafer W1 and the second wafer W2 that is bonded onto the first wafer W1.

The first wafer W1 may have a configuration the same as or similar to the first wafer W1 of FIG. 2.

The second wafer W2 includes a second substrate 12, a plurality of second cell plugs CP2 that extend vertically from the second substrate 12, a second source select line SSL2, and a plurality of second word lines WL2 and a second drain select line DSL2 that are vertically stacked below the second substrate 12 to surround the second cell plugs CP2.

The second word lines WL2 may correspond one-to-one to first word lines WL1. The number of the second word lines WL2 may be the same as the number of the first word lines WL1.

The second source select line SSL2 is disposed between an uppermost second word line WL2 among the plurality of second word lines WL2 and the second substrate 12, and the second drain select line DSL2 is disposed below a lowermost second word line WL2 among the plurality of second word lines WL2.

The second cell plugs CP2 extend into the second substrate 12 by vertically passing through the second drain select line DSL2, the second word lines WL2, the second source select line SSL2 and second interlayer insulating layers 22.

Second source select transistors may be configured in areas where the second source select line SSL2 surrounds the second cell plugs CP2. Second memory cells may be configured in areas where the second word lines WL2 surround the second cell plugs CP2. Second drain select transistors may be configured in areas where the second drain select line DSL2 surrounds the second cell plugs CP2. The second memory region MR2 includes the second word lines WL2 and the second memory cells that are connected to the second word lines WL2.

FIG. 14 illustrates that the first wafer W1 includes a plurality of first bit lines BL1, the second wafer W2 includes a plurality of second bit lines BL2, which vertically overlap the plurality of first bit lines BL1, first cell plugs CP1 are connected to the first bit lines BL1 and the second cell plugs CP2 are connected to the second bit lines BL2, but the present disclosure is not limited thereto.

As another example, a first wafer may include a plurality of odd bit lines and a plurality of dummy even bit lines, a second wafer may include a plurality of even bit lines and a plurality of dummy odd bit lines, first cell plugs may be connected to the odd bit lines, and second cell plugs may be connected to the even bit lines.

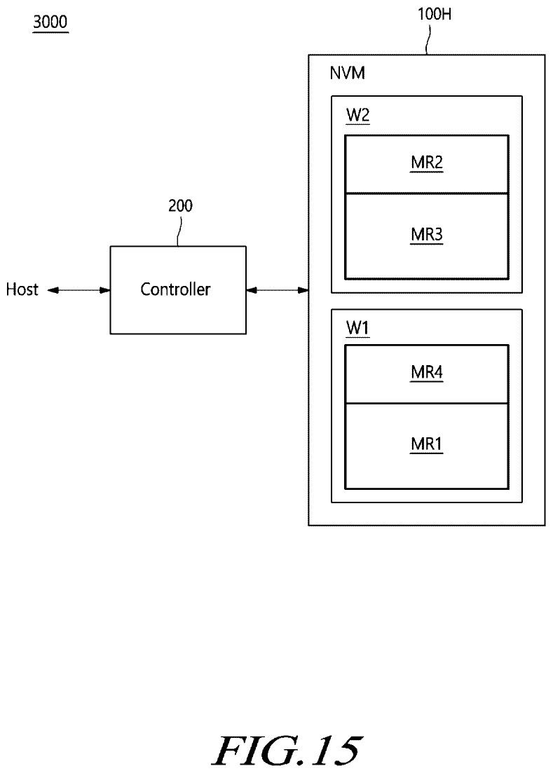

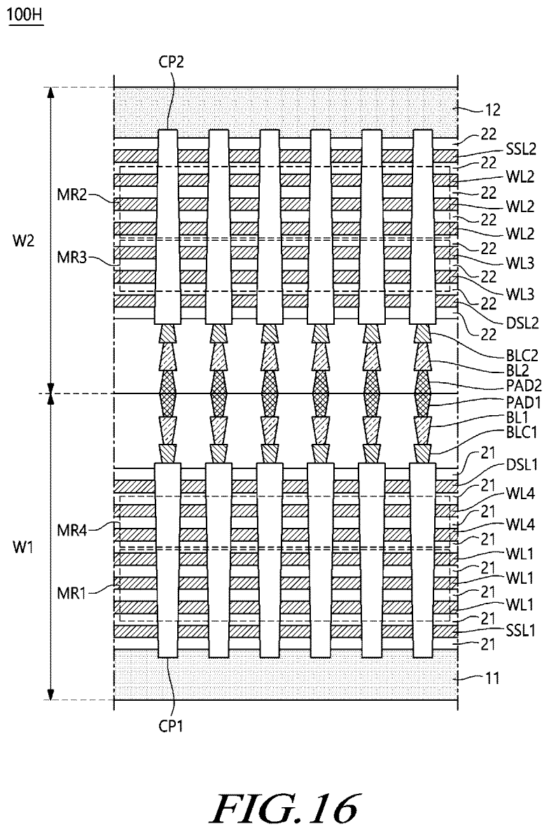

FIG. 15 is a block diagram schematically illustrating a storage device according to an embodiment of the present disclosure, and FIG. 16 is a cross-sectional view of a memory device of FIG. 15. For the sake of simplicity in explanation, configurations that overlap those described above with reference to FIGS. 1 and 2 will be briefly described or omitted.

Referring to FIG. 15, a storage device 3000 includes a memory device 100H and a controller 200. The memory device 100H may be a non-volatile memory NVM.

The memory device 100H includes a first wafer W1 and a second wafer W2. The first wafer W1 includes a first memory region MR1 and a fourth memory region MR4, and the second wafer W2 includes a second memory region MR2 and a third memory region MR3.

The first memory region MR1 includes a plurality of first word lines and first memory cells, which are connected to the plurality of first word lines. The fourth memory region MR4 includes a plurality of fourth word lines and fourth memory cells, which are connected to the plurality of fourth word lines.

The second memory region MR2 includes a plurality of second word lines and second memory cells, which are connected to the plurality of second word lines. The third memory region MR3 includes a plurality of third word lines and third memory cells, which are connected to the plurality of third word lines.

The controller 200 may classify data into a first type or a second type. For example, the first type of data may be cold data, and the second type of data may be hot data.

The controller 200 may encode the first type of data to generate a first code and a second code, may store the first code in one of the first memory cells of the first memory region MR1, and may store the second code in one of the second memory cells of the second memory region MR2. The controller 200 may encode the second type of data to generate a third code, and may store the third code in one of the third memory cells of the third memory region MR3 and the fourth memory cells of the fourth memory region MR4.

Referring to FIG. 16, the memory device 100H includes the first wafer W1 and the second wafer W2 that vertically overlap each other.

The first wafer W1 includes a first substrate 11, a plurality of first cell plugs CP1 that extend vertically from the first substrate 11, and a first source select line SSL1, a plurality of first word lines WL1, a plurality of fourth word lines WL4 and a first drain select line DSL1, which are vertically stacked on the first substrate 11 to surround the first cell plugs CP1.

The first source select line SSL1 is disposed between a lowermost first word line WL1 among the plurality of first word lines WL1 and the first substrate 11, and the first drain select line DSL1 is disposed on an uppermost fourth word line WL4 among the plurality of fourth word lines WL4.

First interlayer insulating layers 21 are disposed among the first source select line SSL1, the first word lines WL1, the fourth word lines WL4 and the first drain select line DSL1. The first interlayer insulating layers 21 are alternately stacked with the first source select line SSL1, the first word lines WL1, the fourth word lines WL4 and the first drain select line DSL1, thereby isolating the first source select line SSL1, the first word lines WL1, the fourth word lines WL4 and the first drain select line DSL1 from each other.

The first cell plugs CP1 extend into the first substrate 11 by vertically passing through the first drain select line DSL1, the fourth word lines WL4, the first word lines WL1, the first source select line SSL1 and the first interlayer insulating layers 21.

First source select transistors may be configured in areas where the first source select line SSL1 surrounds the first cell plugs CP1. The first memory cells may be configured in areas where the first word lines WL1 surround the first cell plugs CP1. The fourth memory cells may be configured in areas where the fourth word lines WL4 surround the first cell plugs CP1. First drain select transistors may be configured in areas where the first drain select line DSL1 surrounds the first cell plugs CP1.

The first memory region MR1 includes the first word lines WL1 and the first memory cells, which are connected to the first word lines WL1. The fourth memory region MR4 includes the fourth word lines WL4 and the fourth memory cells, which are connected to the fourth word lines WL4.

FIG. 16 illustrates that the first wafer W1 includes a plurality of first bit lines BL1, the second wafer W2 includes a plurality of second bit lines BL2 that vertically overlap the plurality of first bit lines BL1, the first cell plugs CP1 are connected to the first bit lines BL1 and second cell plugs CP2 are connected to the second bit lines BL2, but the present disclosure is not limited thereto.

As another example, a first wafer may include a plurality of odd bit lines and a plurality of dummy even bit lines, a second wafer may include a plurality of even bit lines and a plurality of dummy odd bit lines, first cell plugs may be connected to the odd bit lines, and second cell plugs may be connected to the even bit lines.

While the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A storage device comprising:
a memory device and a controller,
the memory device comprising:
a first wafer including a plurality of first word lines that are vertically stacked and a plurality of first memory cells that are connected to the plurality of first word lines; and
a second wafer including a plurality of second word lines and a plurality of third word lines that are vertically stacked, a plurality of second memory cells that are connected to the plurality of second word lines, and a plurality of third memory cells that are connected to the plurality of third word lines,
wherein the controller encodes a first type of data to generate a first code and a second code, stores the first code in one of the plurality of first memory cells, and stores the second code in one of the plurality of second memory cells, and
wherein the controller encodes a second type of data to generate a third code, and stores the third code in one of the plurality of third memory cells.

2. The storage device according to claim 1, wherein the first type of data includes cold data, and the second type of data includes hot data.

3. The storage device according to claim 1, wherein the first type of data is n bits, each of the first code and the second code is k bits, and k is less than n.

4. The storage device according to claim 1, wherein the controller comprises:
an encoder configured to encode the first type of data using a first map table to generate the first code and the second code;
a signal mapping part configured to map code states to the first code and the second code, to generate a first input pulse using the first code and a second input pulse using the second code, and to apply the first input pulse to a first memory cell and the second input pulse to a second memory cell;
a signal de-mapping part configured to de-map a first output pulse from the first memory cell to generate a first code and to de-map a second output pulse from the second memory cell to generate a second code; and
a decoder configured to decode the de-mapped first code and the de-mapped second code using the first map table to restore data.

5. The storage device according to claim 4, wherein
the encoder encodes the second type of data using a second map table to generate the third code,
the signal mapping part maps a code-state to the third code so that a third input pulse according to the third code is applied to a third memory cell,
the signal de-mapping part generates a third code that is de-mapped from a third output pulse outputted from the third memory cell, and
the decoder decodes the de-mapped third code using the second map table to restore data.

6. The storage device according to claim 1, wherein the first wafer and the second wafer are bonded to each other.

7. The storage device according to claim 1, wherein one of the first wafer and the second wafer further includes a logic circuit that controls the first, second and third memory cells.

8. The storage device according to claim 1, wherein
the first wafer includes a memory structure and a logic structure that vertically overlaps the memory structure,
the memory structure includes the plurality of first memory cells, and
the logic structure includes a logic circuit that controls the first, second and third memory cells.

9. The storage device according to claim 1, wherein
the second wafer includes a memory structure and a logic structure that vertically overlaps the memory structure,
the memory structure includes the second and third memory cells, and
the logic structure includes a logic circuit that controls the first, second and third memory cells.

10. The storage device according to claim 1, further comprising:
a third wafer vertically overlapping the first and second wafers,
wherein the third wafer includes a logic circuit, which controls the first, second and third memory cells.

11. A storage device comprising:
a memory device having a first wafer and a second wafer that vertically overlap each other; and
a controller,
the first wafer including:
a plurality of first word lines that are vertically stacked;
a plurality of odd cell plugs that vertically pass through the plurality of first word lines and are connected to a plurality of odd bit lines; and
a plurality of first memory cells that are disposed in areas where the plurality of first word lines surround the plurality of odd cell plugs,
the second wafer including:
a plurality of second word lines and a plurality of third word lines that are vertically stacked;
a plurality of even cell plugs that vertically pass through the pluralities of second and third word lines and are connected to a plurality of even bit lines;
a plurality of second memory cells that are disposed in areas where the plurality of second word lines surround the plurality of even cell plugs; and
a plurality of third memory cells that are disposed in areas where the plurality of third word lines surround the plurality of even cell plugs, and
wherein the controller encodes a first type of data to generate a first code and a second code, stores the first code in one of the plurality of first memory cells, and stores the second code in one of the plurality of second memory cells, and
wherein the controller encodes a second type of data to generate a third code, and stores the third code in one of the plurality of third memory cells.

12. The storage device according to claim 11, wherein the first type of data includes cold data, and the second type of data includes hot data.

13. The storage device according to claim 11, wherein
the first wafer further includes a plurality of dummy even bit lines that are disposed alternately with the plurality of odd bit lines in a second direction intersecting a first direction in which the plurality of odd bit lines extend, and
the second wafer further includes a plurality of dummy odd bit lines that are disposed alternately with the plurality of even bit lines in the second direction.

14. The storage device according to claim 13, wherein the plurality of odd cell plugs are not vertically aligned with the plurality of even cell plugs.

15. The storage device according to claim 11, wherein one of the first wafer and the second wafer further includes a logic circuit that controls the pluralities of first, second and third memory cells.

16. The storage device according to claim 11, further comprising:
a third wafer vertically overlapping the first and second wafers,
wherein the third wafer includes a logic circuit that controls the pluralities of first, second and third memory cells.

17. The storage device according to claim 15, wherein
the logic circuit includes a page buffer, and
one of the plurality of odd bit lines and one of the plurality of even bit lines share the page buffer.

18. A storage device comprising:
a memory device having a first wafer and a second wafer that vertically overlap each other; and
a controller,
the first wafer including:
a plurality of first word lines and a plurality of second word lines that are vertically stacked;
a plurality of first memory cells that are connected to the plurality of first word lines; and
a plurality of second memory cells that are connected to the plurality of second word lines,
the second wafer including:
a plurality of third word lines and a plurality of fourth word lines that are vertically stacked;
a plurality of third memory cells that are connected to the plurality of third word lines; and
a plurality of fourth memory cells that are connected to the plurality of fourth word lines,
wherein the controller encodes a first type of data to generate a first code and a second code, stores the first code in one of the plurality of first memory cells, and stores the second code in one of the plurality of third memory cells, and
wherein the controller encodes a second type of data to generate a third code, and stores the third code in one of the pluralities of second and fourth memory cells.

19. A storage device comprising:
a memory device including a first wafer and a second wafer that vertically overlap each other; and
a controller,
the first wafer including:
a plurality of first word lines which are vertically stacked;
a plurality of first cell plugs that vertically pass through the plurality of first word lines; and
a plurality of first memory cells that are disposed in areas where the plurality of first word lines surround the plurality of first cell plugs,
the second wafer including:
a plurality of second word lines that are vertically stacked;
a plurality of second cell plugs that vertically pass through the plurality of second word lines; and
a plurality of second memory cells that are disposed in areas where the plurality of second word lines surround the plurality of second cell plugs,
wherein the controller encodes data to generate a first code and a second code, stores the first code in one of the plurality of first memory cells, and stores the second code in one of the plurality of second memory cells.

20. The storage device according to claim 19, wherein
the plurality of first cell plugs are connected to odd bit lines, and
the plurality of second cell plugs are connected to even bit lines.
